(19) United States
(12) Patent Application Publication
(10) Pub. No.: US 2014/0198377 A1
(43) Pub. Date: Jul. 17, 2014

(54) LASER OSCILLATOR

(71) Applicant: OMRON CORPORATION, Kyoto (JP)

(72) Inventors: Masao YOSHIOKA, Fukuoka (JP); Takuya TOGAWA, Tokyo (JP)

(73) Assignee: OMRON CORPORATION, Kyoto (JP)

(21) Appl. No.: 14/100,300

(22) Filed: Dec. 9, 2013

(30) Foreign Application Priority Data
Jan. 15, 2013 (JP) 2013-004707

(51) Int. Cl. H01S 3/067; H01S 5/14

(52) U.S. Cl. CPC H01S 3/06754; H01S 5/14
USPC 359/341.1; 372/97

(57) ABSTRACT

A single mode semiconductor laser includes a first optical resonator, which is formed by a total reflection surface and a partial reflection surface. Light emitted from the partial reflection surface of the single mode semiconductor laser enters a fiber Bragg grating, which includes a diffraction grating formed therein. The diffraction grating forms a second optical resonator in combination with the total reflection surface of the single mode semiconductor laser. A fiber amplifier amplifies a laser beam emitted from the fiber Bragg grating.

### CROSS-REFERENCE TO RELATED APPLICATION

The disclosure of Japanese Patent Application No. 2013-004707 filed Jan. 15, 2013, including the specification, drawings, and claims is expressly incorporated herein by reference in its entirety.

### BACKGROUND

1. Field of Disclosure

The present disclosure relates to a laser oscillator, and particularly to a laser oscillator that can be preferably used to improve uniformity of the light intensity distribution in a cross section of a laser beam by allowing the laser beam to pass through an optical fiber.

2. Background Information

Recently, a technique has been developed for obtaining a laser beam whose cross section has a highly uniform light intensity distribution (hereinbelow, referred to as a flat-top beam). For example, obtaining a flat-top beam by allowing a laser beam to pass through an optical fiber has been proposed (see Japanese Unexamined Patent Publications No. 2009-168914 and No. 2011-189389, for example).

Conventionally, there has been proposed obtaining a laser beam that expands within a wide wavelength range from a laser beam having any wavelength by using stimulated Raman scattering or stimulated Brillouin scattering (see Japanese Unexamined Patent Publication No. 2002-353539, for example). Specifically, in the invention described in Japanese Unexamined Patent Publication No. 2002-353539, a laser beam having a wavelength λ1 is introduced into an optical fiber from a Nd:YAG laser, and reflected by a fiber Bragg grating (FBG). As a result, stimulated Raman scattering is activated. In addition, a pair of chirped fiber Bragg gratings (CFBGs) which reflects a laser beam having a wavelength range Δλ1 including a wavelength λ2 is provided between the Nd:YAG laser and the FBG. As a result, a laser beam having the wavelength λ2 is caused to oscillate by the CFBGs, and a multiwavelength laser beam is caused to oscillate by stimulated Brillouin scattering. Accordingly, a laser beam having the wavelength range Δλ1 can be obtained from a laser beam having the wavelength λ1.

Here, a case where a laser beam emitted from a fiber laser is allowed to pass through an optical fiber to obtain a flat-top beam will be considered with reference to FIGS. 1 to 3.

A laser oscillator 11 illustrated in FIG. 1 is composed of a fiber laser that includes a seed laser diode (seed LD) 21 and a fiber amplifier 22. A laser beam emitted from the laser oscillator 11 is introduced into a square optical fiber 13 that includes a core having a rectangular cross section through a lens system 12, passes through the square optical fiber 13, and is emitted therefrom.

FIG. 2 schematically illustrates a measurement result of the beam profile of a laser beam emitted from the square optical fiber 13 on an irradiation surface. As shown in this example, multiple speckles are generated on the irradiation surface, and variation in the light intensity distribution is generated. This is because of that each laser beam emitted from the laser oscillator 11 has a narrow spectral width and high coherence, and interference of laser beams is therefore likely to occur.

For example, FIG. 3 illustrates an example of the trajectory of a laser beam passing through the square optical fiber 13. When laser beams which have passed through the square optical fiber 13 along different trajectories are directed to the same position on the irradiation surface as shown by arrows in FIG. 3, since the laser beams have the same wavelength, the laser beams interfere with each other. Further, the laser beams having the same wavelength emitted from the square optical fiber 13 interfere with each other on the irradiation surface with an irregular phase relationship therebetween, and an irregular interference pattern is thereby generated. Accordingly, speckles increase, and variation in the light intensity distribution is generated. As a result, unevenness in laser processing is generated, and the processing quality is thereby deteriorated.

### SUMMARY

The present disclosure has been devised to improve, when allowing a laser beam emitted from a laser oscillator to pass thorough an optical fiber, uniformity of the light intensity distribution in the cross section of the laser beam.

A laser oscillator of a first aspect of the present disclosure includes a single mode semiconductor laser having a first optical resonator, the first optical resonator being formed by a total reflection surface and a partial reflection surface. A fiber Bragg grating is provided where light emitted from the partial reflection surface of the single mode semiconductor laser enters. The fiber Bragg grating includes a diffraction grating formed therein, in which the diffraction grating being configured to form (forms) a second optical resonator in combination with the total reflection surface of the single mode semiconductor laser. A fiber amplifier configured to amplify (amplifies) a laser beam emitted from the fiber Bragg grating.

In the laser oscillator of the first aspect of the present disclosure, laser beams having different wavelengths are caused to oscillate by the first optical resonator and the second optical resonator, and then amplified.

Accordingly, it is possible to widen the spectral width of a laser beam emitted from the laser oscillator. Further, when allowing a laser beam emitted from the laser oscillator to pass through an optical fiber, it is possible to improve uniformity of the light intensity distribution in the cross section of the laser beam.

A plurality of diffraction gratings having different reflection bands may be formed in the fiber Bragg grating.

As a result, it is possible to further widen the spectral width of a laser beam emitted from the laser oscillator with a simple structure.

Each of the reflection bands of the plurality of diffraction gratings may partially overlap with an adjacent reflection band (of the different reflection bands), and a reflection band in which the reflection bands of the plurality of diffraction gratings overlap with each other may include a peak wavelength of the single mode semiconductor laser. That is, each of the different reflection bands of the plurality of diffraction gratings partially overlaps with an adjacent reflection band of the different reflection bands, and a reflection band of the different reflection bands includes a peak wavelength of the single mode semiconductor laser.

A reflection band of the diffraction grating may be wider than a spectral width of the single mode semiconductor laser, and may include a peak wavelength of the single mode semiconductor laser.

A laser beam emitted from the fiber amplifier may be allowed to pass through an optical fiber, and then directed to a processing target.

As a result, the processing object can be irradiated with a laser beam whose cross section has a highly uniform light intensity distribution, and the processing quality is thereby improved.

A laser oscillator of a second aspect of the present disclosure includes a single mode semiconductor laser having a first optical resonator. The first optical resonator is formed by a total reflection surface and a partial reflection surface. A fiber Bragg grating is provided where (into which) light emitted from the partial reflection surface of the single mode semiconductor laser enters. The fiber Bragg grating includes a diffraction grating formed therein, in which the diffraction grating being configured to form (forms) a second optical resonator in combination with the total reflection surface of the single mode semiconductor laser. The laser oscillator of the second aspect emits a laser beam emitted from the fiber Bragg grating.

In the laser oscillator of the second aspect of the present disclosure, laser beams having different wavelengths are caused to oscillate by the first optical resonator and the second optical resonator, and then emitted therefrom.

Accordingly, it is possible to widen the spectral width of a laser beam emitted from the laser oscillator. Further, when allowing a laser beam emitted from the laser oscillator to pass through an optical fiber, it is possible to improve uniformity of the light intensity distribution in the cross section of the laser beam.

According to the first aspect or the second aspect of the present disclosure, it is possible to widen the spectral width of a laser beam emitted from the laser oscillator. Further, according to the first aspect or the second aspect of the present disclosure, when allowing a laser beam emitted from the laser oscillator to pass through an optical fiber, it is possible to improve uniformity of the light intensity distribution in the cross section of a laser beam.

### BRIEF DESCRIPTION OF THE DRAWINGS

FIG. 1 is a diagram illustrating an example of a conventional laser processing apparatus;

FIG. 2 is a diagram illustrating an example of the beam profile of a laser beam emitted from the conventional laser processing apparatus;

FIG. 3 is a diagram illustrating an example of the trajectory of a laser beam passing through a square optical fiber of the conventional laser processing apparatus;

FIG. 4 is a diagram illustrating an embodiment of a laser processing apparatus to which the present disclosure is applied;

FIG. 5 is a diagram illustrating an example of the configuration of a seed laser diode (seed LD);

FIG. 6 is a diagram illustrating an example of the configuration of a fiber Bragg grating (FBG);

FIG. 7 is a graph illustrating an example of the reflective property of the FBG;

FIG. 8 is a diagram for explaining the principle of laser oscillation of a laser oscillator to which the present disclosure is applied;

FIG. 9 is a diagram illustrating an example of the spectrum of a laser beam emitted from the laser oscillator to which the present disclosure is applied;

FIG. 10 is a diagram illustrating an example of the beam profile of a laser beam emitted from the laser processing apparatus to which the present disclosure is applied; and

FIG. 11 is a diagram illustrating an example of the trajectory of a laser beam passing through a square optical fiber of the laser processing apparatus to which the present disclosure is applied.

### DETAILED DESCRIPTION

Hereinbelow, an embodiment will be described with reference to the drawings. The description will be made in the following order.

### 1. Embodiment

### 2. Modifications

### 1. Embodiment

### Example of Configuration of Laser Processing Apparatus

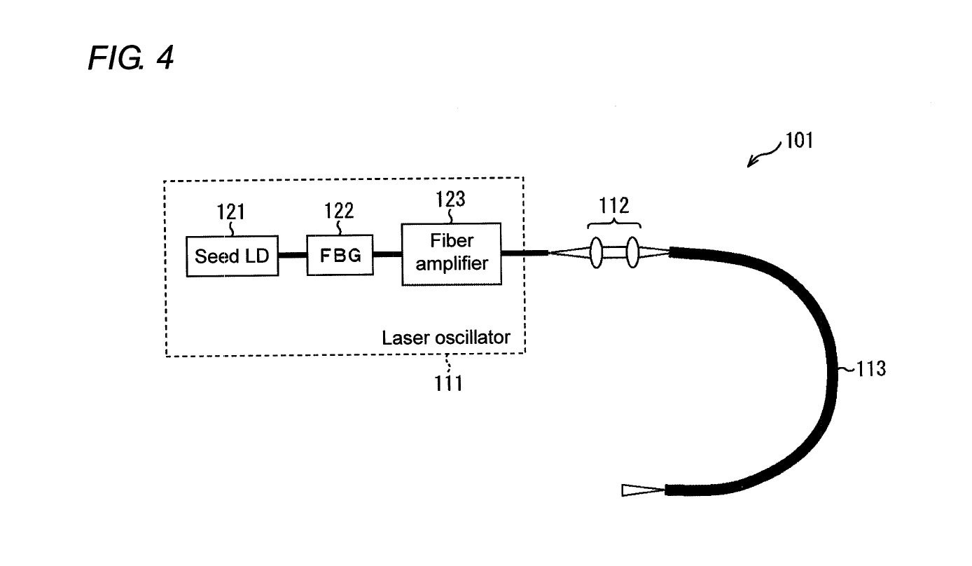

FIG. 4 illustrates an exemplary embodiment of a laser processing apparatus 101 according to an aspect of the present disclosure. The laser processing apparatus 101 is used, for example, in processing of a thin-film photovoltaic panel or an organic electroluminescence (organic EL). The laser processing apparatus 101 is configured to include a laser oscillator 111, a lens system 112, and a square optical fiber 113.

The laser oscillator 111 includes a fiber laser that amplifies a laser beam by a fiber amplifier 123. The laser oscillator 111 is configured to include a seed laser diode (seed LD) 121, a fiber Bragg grating (FBG) 122, and the fiber amplifier 123.

The seed LD 121 includes, for example, a typical single mode semiconductor laser. The seed LD 121 causes a laser beam having a predetermined wavelength to oscillate and emits the oscillating laser beam therefrom. Hereinbelow, a case where the seed LD 121 causes a laser beam having a peak wavelength of 1062 nm to oscillate will be described as an example.

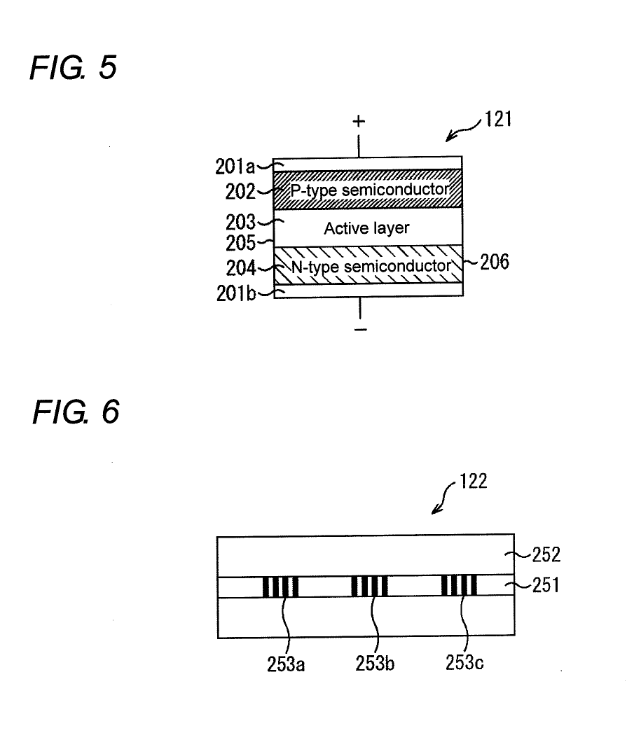

FIG. 5 illustrates an example of the configuration of the seed LD 121. The seed LD 121 has a configuration in which a P-type semiconductor 202, an active layer 203, and an N-type semiconductor 204 are laminated between a positive electrode 201a and a negative electrode 201b. A total reflection surface 205 is formed on one of side surfaces of the seed LD 121, the side surfaces being perpendicular to the respective layers of the seed LD 121 and opposed to each other, and a partial reflection surface 206 is formed on the other surface thereof. The total reflection surface 205 and the partial reflection surface 206 form an optical resonator (hereinbelow, referred to as an internal resonator).

Referring back to FIG. 4, the FBG 122 is arranged so as to face the partial reflection surface 206 of the seed LD 121. Light emitted from the partial reflection surface 206 enters the FBG 122. The FBG 122 is connected to the seed LD 121, for example, by fusion.

FIG. 6 illustrates an example of the configuration of the FBG 122. The FBG 122 includes an optical fiber that includes a core 251 and a cladding 252. In the core 251, three diffraction gratings 253a to 253c having different center wavelengths (Bragg wavelengths) are arranged in an optical axis direction.

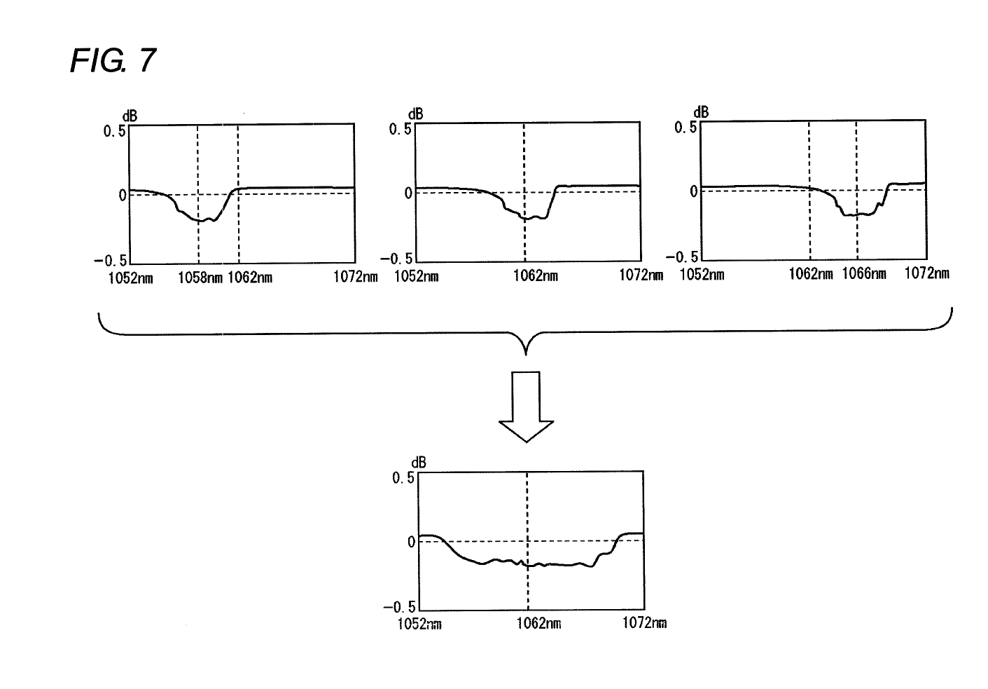

FIG. 7 illustrates an example of the reflective properties of the diffraction gratings 253a to 253c and the entire FBG 122. Specifically, in FIG. 7, the upper left graph illustrates the reflective property of the diffraction grating 253a, the upper center graph illustrates the reflective property of the diffraction grating 253b, and the upper right graph illustrates the reflective property of the diffraction grating 253c. Further, the lower graph in FIG. 7 illustrates the reflective property of the entire FBG 122.

The width of the reflection band of each of the diffraction gratings 253a to 253c is wider than the width of the reflection band of a diffraction grating of a typical FBG as well as wider than the spectral width of the seed LD 121. Specifically, the reflection band of the diffraction grating 253a has a width of approximately 4 nm centered at 1058 nm. The reflection band of the diffraction grating 253b has a width of approximately 4 nm centered at 1062 nm which is the same as the peak wavelength of the seed LD 121. The reflection band of the diffraction grating 253c has a width of approximately 4 nm centered at 1066 nm.

Each of the reflection bands partially overlaps with an adjacent reflection band. Specifically, the long-wavelength side of the reflection band of the diffraction grating 253a partially overlaps with the short-wavelength side of the reflection band of the diffraction grating 253b. Further, the long-wavelength side of the reflection band of the diffraction grating 253b partially overlaps with the short-wavelength side of the reflection band of the diffraction grating 253c. The reflection band of the entire FBG 122 in which the reflection bands of the diffraction gratings 253a to 253c overlap with each other has a width of approximately 8 nm centered at 1062 nm.

In this manner, the FBG 122 having a wide reflection band can be easily obtained by forming the diffraction gratings 253a to 253c having different reflection bands.

As will be described later, the total reflection surface 205 of the seed LD 121 in combination with the respective diffraction gratings 253a to 253c of the FBG 122 forms three optical resonators (hereinbelow, referred to as external resonators). In each of the external resonators, a laser beam having a wavelength that is different from that of the seed LD 121 oscillates. Then, a laser beam oscillating in the seed LD 121 alone and laser beams oscillating in the respective external resonators are emitted from the FBG 122, and enter the fiber amplifier 123.

In the following description, when it is not necessary to distinguish the diffraction gratings 253a to 253c from each other, the diffraction gratings 253a to 253c are merely referred to as diffraction gratings 253.

Referring back to FIG. 4, the fiber amplifier 123 uses an optical fiber as a medium. The fiber amplifier 123 amplifies a laser beam emitted from the FBG 122 and emits the amplified laser beam therefrom. The laser beam emitted from the fiber amplifier 123 is introduced into the square optical fiber 113 through the lens system 112.

The square optical fiber 113 includes the core having a rectangular cross section, and forms the introduced laser beam so as to have a rectangular cross section and emits the formed laser beam therefrom. As will be described later, the laser beam emitted from the square optical fiber 113 becomes a flat-top beam whose cross section has a highly uniform light intensity distribution.

The laser beam emitted from the square optical fiber 113 is directed to a processing target such as a thin-film photovoltaic panel and an organic electroluminescence (organic EL) through a processing optical system (not shown), so that laser processing is performed.

[Principle of Laser Beam Emitted from Square Optical Fiber 113 Becoming Flat-Top Beam]

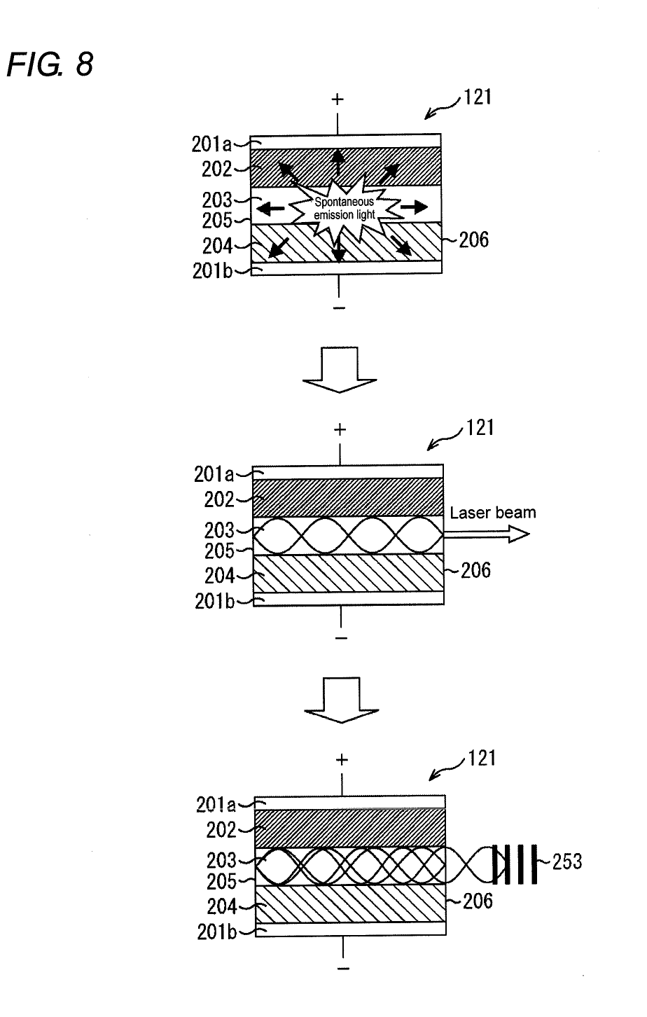

Next, the principle of a laser beam emitted from the square optical fiber 113 becoming a flat-top beam will be described with reference to FIGS. 8 to 11.

As illustrated in FIG. 8, when voltage is applied between the electrode 201a and the electrode 201b of the seed LD 21, spontaneous emission light is generated in the active layer 203. The wavelength characteristic of the spontaneous emission light approximately follows a Gaussian distribution, and the spontaneous emission light has a relatively wide bandwidth (approximately 200 nm, for example) centered at a predetermined wavelength (1062 nm, for example). Then, in the active layer 203, stimulated emission is caused by the spontaneous emission light as seed light, and stimulated emission light is thereby generated. In addition, in the internal resonator formed by the total reflection surface 205 and the partial reflection surface 206, the spontaneous emission light and the stimulated emission light move back and forth between the total reflection surface 205 and the partial reflection surface 206, which causes stimulated emission. At this moment, light having a wavelength that satisfies “the cavity length of the internal resonator=the integral multiple of the wavelength” resonates and is amplified in the internal resonator. In this manner, a laser beam having a predetermined wavelength (1062 nm, for example) oscillates. Then, the oscillating laser beam and light including a part of the spontaneous emission light and a part of the stimulated emission light are emitted from the partial reflection surface 206.

Further, also in each of the external resonators which are formed by the partial reflection surface 206 in combination with the respective diffraction gratings 253 of the FBG 122, a laser beam having a predetermined wavelength oscillates in the same manner as in the internal resonator. Then, the laser beam oscillating in the internal resonator (the seed LD 121 alone) and the laser beams oscillating in the respective external resonators are emitted from the FBG 122 toward the fiber amplifier 123.

In each of the external resonators, a laser beam having a wavelength that is within the reflection band of the corresponding diffraction grating 253 and satisfies “the cavity length of the corresponding external resonator=the integral multiple of the wavelength” oscillates.

In this manner, in the seed LD 21 (the internal resonator) and the respective external resonators, laser beams of a plurality of wavelengths including the peak wavelength of the seed LD21 and wavelengths near the peak wavelength of the seed LD 21 oscillate. As a result, a laser beam that has a wider spectral width than a laser beam emitted from the seed LD 121 alone is emitted from the laser oscillator 111.

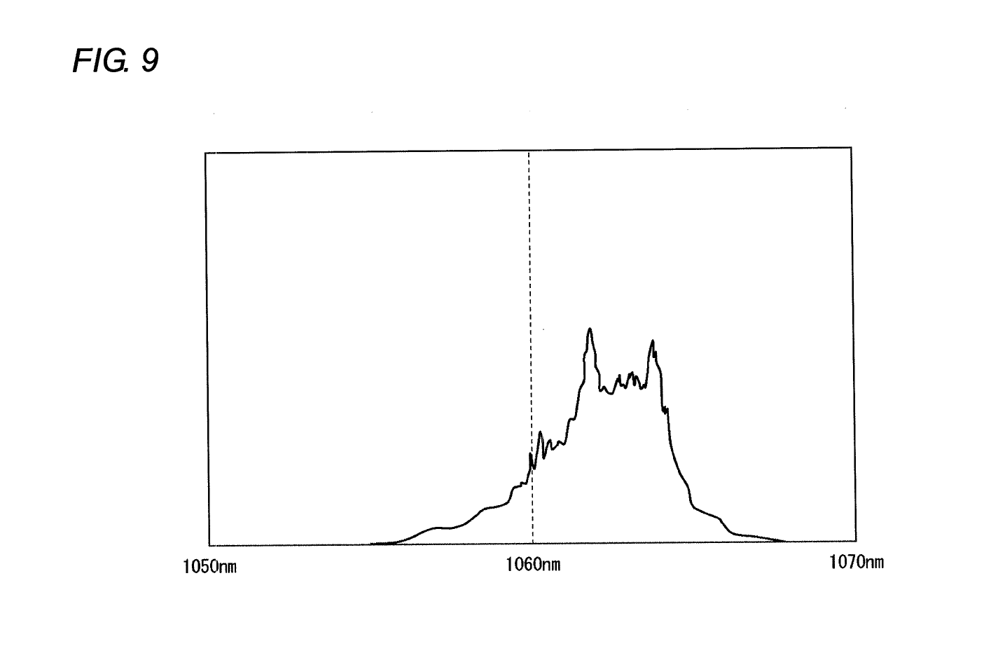

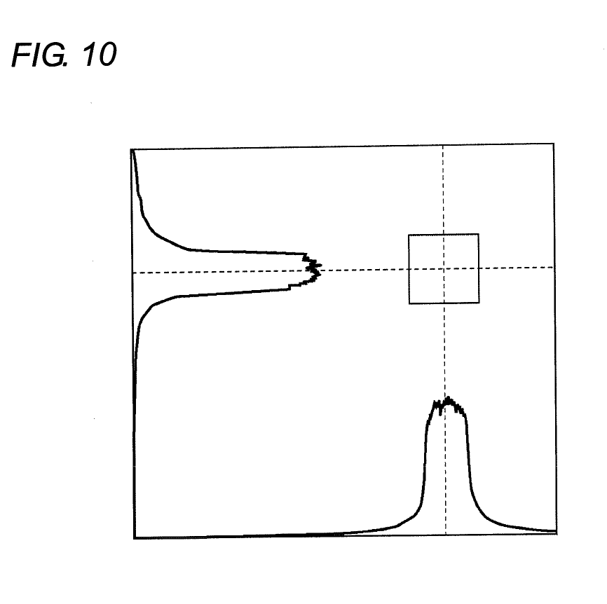

FIG. 9 is an example of the spectrum of a laser beam emitted from the laser oscillator 111. As shown in this example, a laser beam emitted from the laser oscillator 111 has peaks not only at 1062 nm which is the peak wavelength of the seed LD 121, but also near the center wavelength of each of the diffraction gratings 253 of the FBG 122, and has a widened spectral width.

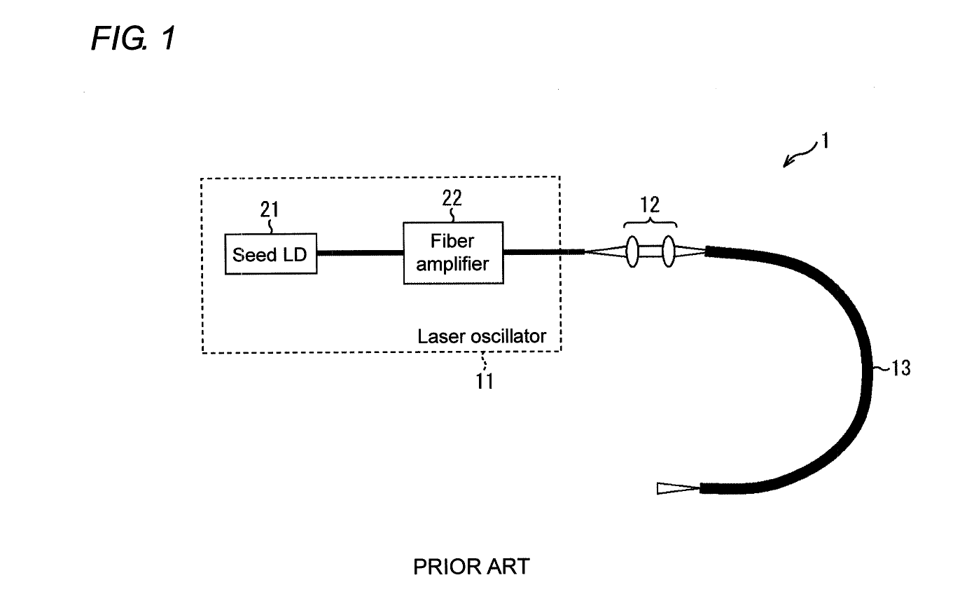

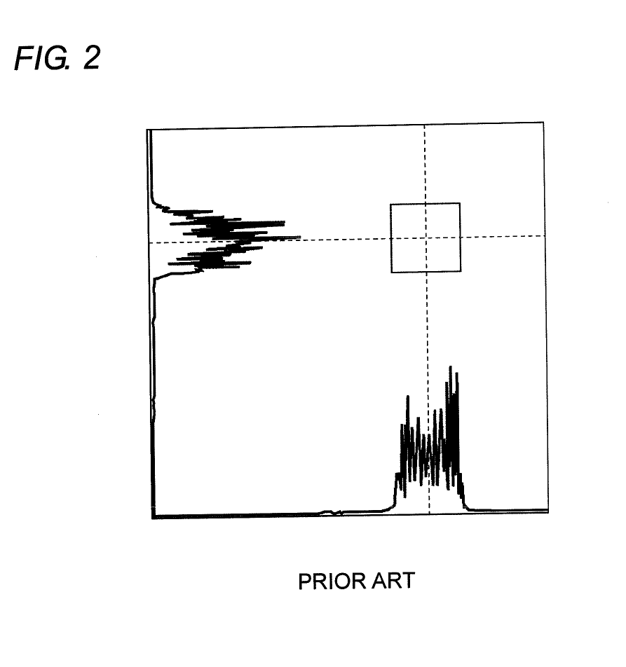

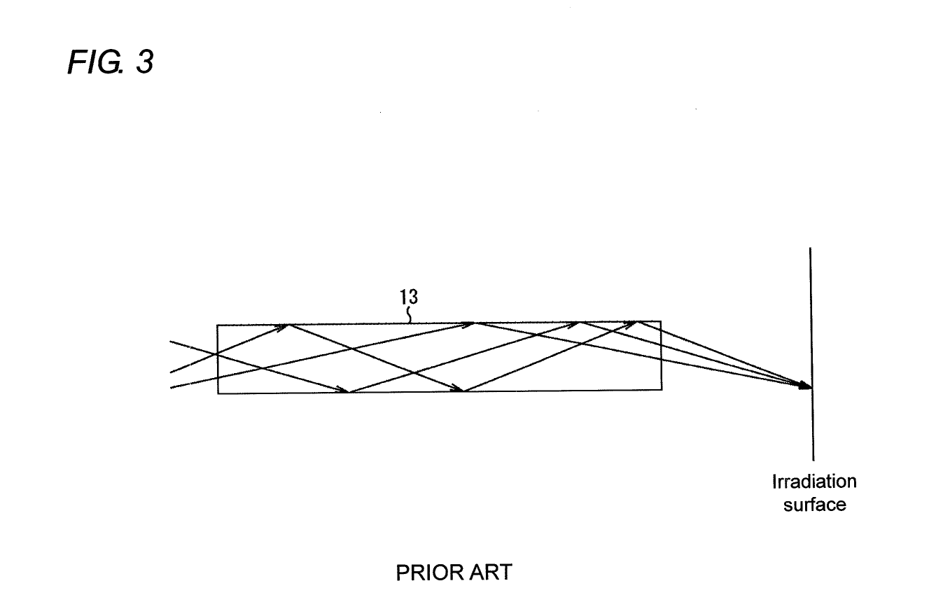

FIG. 10 schematically illustrates a measurement result of the beam profile of a laser beam emitted from the square optical fiber 113 on the irradiation surface. In comparison with the example illustrated in FIG. 2, speckles are reduced, and the light intensity distribution becomes substantially uniform. This is because of that a laser beam emitted from the laser oscillator 111 has a wider spectral width and a lower coherence than a laser beam emitted from the conventional laser oscillator 11 (FIG. 1), and interference of laser beams is therefore not likely to occur.

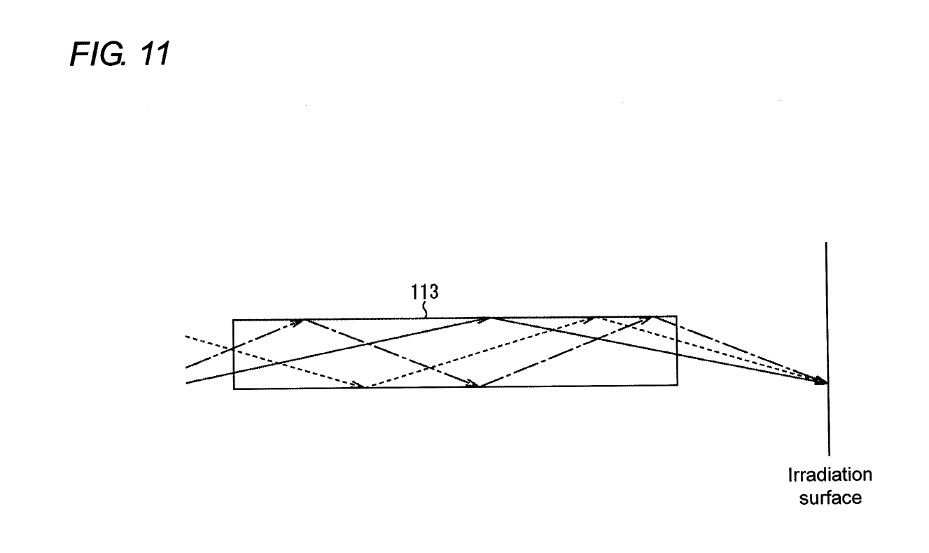

For example, FIG. 11 illustrates an example of the trajectory of a laser beam that is emitted from the square optical fiber 113 in the same manner as illustrated in FIG. 1. The difference in the line types of the respective arrows indicates the difference in wavelength. Even if laser beams having different wavelengths are directed to the same position on the irradiation surface as illustrated in FIG. 11, the laser beams do not interfere with each other.

Further, the spectral width of each laser beam is widened and the coherence thereof is lowered, thereby reducing the possibility that laser beams passing through the square optical fiber 113 along different trajectories may be directed to the same position on the irradiation surface, and the laser beams may thereby interfere with each other. Thus, speckles of a laser beam are reduced on the irradiation surface, and uniformity of the light intensity distribution is improved. As a result, unevenness in laser processing is reduced, and the processing quality is thereby improved.

Since the laser oscillator 111 can be achieved with a simple structure that is only required to connect the FBG 122 to the seed LD 121, occurrence of the necessity of various adjustment operations, increase in the size of the apparatus, increase in the cost and the like can be prevented.

Further, since the laser processing apparatus 101 uses the laser oscillator 111 that includes a fiber laser, it is possible to more easily and independently adjust the repetition frequency, the pulse width, the output intensity and the like of a laser beam than a laser processing apparatus that uses another solid-state laser.

### 2. Modifications

Hereinbelow, modifications of the above-described embodiment of the present disclosure will be described.

For example, the number of diffraction gratings 253 formed in the FBG 122 is not limited to three, and can be set to any number as long as it is one or larger.

The reflective property of each of the diffraction gratings 253 is not limited to the example illustrated in FIG. 7. For example, the center wavelength and the width of the reflection band can be changed according to the wavelength characteristic and the like of the seed LD 121.

The present disclosure can also be applied when using an optical fiber that includes a core whose cross section has a shape other than a rectangular shape (circular shape, for example).

For example, the seed LD 121 and the FBG 122 may be connected to each other not physically by fusion or the like, but optically through a lens or the like.

For example, when a laser beam that has a sufficient intensity for processing can be obtained by the seed LD 121 and the FBG 122, the fiber amplifier 123 may not be provided.

The present disclosure can use an optical component, instead of the FBG 122, that can form an external resonator in combination with the total reflection surface of the seed LD 121.

The embodiment of the present technique is not limited to the embodiment described above, and various modifications can be made without departing from the scope of the present technique.

What is claimed is:

1. A laser oscillator comprising:
a single mode semiconductor laser comprising a first optical resonator, the first optical resonator being formed by a total reflection surface and a partial reflection surface;
a fiber Bragg grating into which light emitted from the partial reflection surface of the single mode semiconductor laser enters, the fiber Bragg grating comprising a diffraction grating formed therein, the diffraction grating forming a second optical resonator in combination with the total reflection surface of the single mode semiconductor laser; and
a fiber amplifier that amplifies a laser beam emitted from the fiber Bragg grating.

2. The laser oscillator according to claim 1, wherein a plurality of diffraction gratings having different reflection bands are formed in the fiber Bragg grating.

3. The laser oscillator according to claim 2, wherein each of the different reflection bands of the plurality of diffraction gratings partially overlaps with an adjacent reflection band of the different reflection bands, and a reflection band of the different reflection bands includes a peak wavelength of the single mode semiconductor laser.

4. The laser oscillator according to claim 1, wherein a reflection band of the diffraction grating is wider than a spectral width of the single mode semiconductor laser, and includes a peak wavelength of the single mode semiconductor laser.

5. The laser oscillator according to claim 1, wherein a laser beam emitted from the fiber amplifier is allowed to pass through an optical fiber, and is then directed to a processing target.

6. A laser oscillator comprising:
a single mode semiconductor laser comprising a first optical resonator, the first optical resonator being formed by a total reflection surface and a partial reflection surface; and
a fiber Bragg grating into which light emitted from the partial reflection surface of the single mode semiconductor laser enters, the fiber Bragg grating comprising a diffraction grating formed therein, the diffraction grating forming a second optical resonator in combination with the total reflection surface of the single mode semiconductor laser,
wherein the laser oscillator emits a laser beam emitted from the fiber Bragg grating.
